(19) United States
(12) Patent Application Publication
(10) Pub. No.: US 2026/0182324 A1
(43) Pub. Date: Jun. 25, 2026

(54) METHOD OF MANUFACTURING WIRING DEVICE

(71) Applicant: AOI ELECTRONICS CO., LTD., Takamatsu-shi (JP)

(72) Inventors: Yoshitaka NAKAMURA, Tokyo (JP); Masato FUKUSHIMA, Tokyo (JP); Shinji WAKISAKA, Tokyo (JP)

(21) Appl. No.: 19/428,393

(22) Filed: Dec. 22, 2025

(30) Foreign Application Priority Data
Dec. 24, 2024 (JP) 2024-227846

(51) Int. Cl. H10W 20/00; H10W 20/42; H10W 20/43

(52) U.S. Cl. CPC H10W 20/056; H10W 20/42; H10W 20/43

(57) ABSTRACT

To provide a method of manufacturing a wiring device capable of improving performance. A method of manufacturing a wiring device includes the steps of: preparing a substrate; forming a first insulating layer on an upper surface of the substrate; removing a part of the first insulating layer to form a groove portion; forming a first conductor layer so as to fill the groove portion of the first insulating layer; and machining a part of the first insulating layer and a part of the first conductor layer to form a first wiring layer.

### CROSS REFERENCES TO RELATED APPLICATIONS

The present application claims priority to Japanese Patent Application No. 2024-227846 filed on Dec. 24, 2024, the disclosure of which is incorporated herein by reference.

### BACKGROUND

The present invention relates to a method of manufacturing a wiring device.

In recent years, there has been a technique called chiplet integration in which a function of a semiconductor chip is divided into a plurality of chips (chiplets) and the chips are combined to form one module. As a result, a highly functional chip module is configured and provided.

In order to implement the chiplet integration, a study is underway on the structure of the chip module, and the connection such as an interposer and a bridge chip.

For example, U.S. Patent Application Publication No. 2021-0005542 describes a module structure using a bridge for performing connection and wiring between chips.

a International Publication No. 2023-022179 describes pillar suspended bridge (PSB) structure, which is a module structure using a bridge that can connect chips with a simpler structure and higher accuracy, and a method of manufacturing the same.

Japanese Patent Application Laid-open Publication No. 2012-060100 describes a manufacturing method in which, using an insulating layer having a groove similar to that in a damascene process, a first film is formed on the groove portion with metal such as Ti, Cr, Ta, and Pd, a second film is formed with metal such as copper that has lower hardness than the metal such as Ti, Cr, Ta, and Pd, and planarization is performed by placing a cutting blade where the first metal film is naturally interrupted and performing machining with the cutting blade instead of chemical mechanical polishing (CMP).

International Publication No. 2017-038110 describes manufacturing method in which a rectangular panel-shaped organic substrate is prepared using an organic material for an insulating layer having a groove similar to that in a damascene process, wiring is formed by embedding a copper paste in the groove, and planarization is performed by fly cutting instead of CMP.

International Publication No. 2017-163743 describes a manufacturing method in which a rectangular panel-shaped organic substrate is prepared using an organic material for an insulating layer having a groove similar to that in a damascene process, a first barrier layer made of any of Ti, Ni, Pd, Cr, Ta, W, and Au is formed on a side wall and a bottom surface of the groove, wiring is formed by filling the groove by metal plating using copper or the like, planarization is performed by CMP or fly cutting, and a second barrier layer is formed by forming a film on an upper surface of the wiring by electroless plating using metal such as Ni.

### SUMMARY

It is necessary to further improve the performance of the wiring device.

A method of manufacturing a wiring device according to one embodiment includes the steps of: (a) preparing a substrate; (b) forming a first insulating layer on an upper surface of the substrate; (c) removing a part of the first insulating layer to form a groove portion; (d) forming a first conductor layer so as to fill the groove portion of the first insulating layer; and (e) machining a part of the first insulating layer and a part of the first conductor layer to form a first wiring layer.

According to the above one embodiment, it is possible to provide the method of manufacturing a wiring device capable of improving the performance.

### BRIEF DESCRIPTION OF THE DRAWINGS

FIG. 1 is a cross-sectional view illustrating a step of a method of manufacturing a wiring device according to one embodiment.

FIG. 2 is a cross-sectional view illustrating a step of the method of manufacturing the wiring device according to the one embodiment, which is a subsequent step to FIG. 1.

FIG. 3 is a cross-sectional view illustrating a step of the method of manufacturing the wiring device according to the one embodiment, which is a subsequent step to FIG. 2.

FIG. 4 is a cross-sectional view illustrating a step of the method of manufacturing the wiring device according to the one embodiment, which is a subsequent step to FIG. 3.

FIG. 5 is a cross-sectional view illustrating a step of the method of manufacturing the wiring device according to the one embodiment, which is a subsequent step to FIG. 4.

FIG. 6 is a cross-sectional view illustrating a step of the method of manufacturing the wiring device according to the one embodiment, which is a subsequent step to FIG. 5.

FIG. 7 is a cross-sectional view illustrating a step of the method of manufacturing the wiring device according to the one embodiment, which is a subsequent step to FIG. 6.

FIG. 8 is a cross-sectional view illustrating a step of the method of manufacturing the wiring device according to the one embodiment, which is a subsequent step to FIG. 7.

FIG. 9 is a cross-sectional view illustrating a step of the method of manufacturing the wiring device according to the one embodiment, which is a subsequent step to FIG. 8.

FIG. 10 is a cross-sectional view illustrating a step of the method of manufacturing the wiring device according to the one embodiment, which is a subsequent step to FIG. 9.

FIG. 11 is an enlarged view of the step of the method of manufacturing the wiring device illustrated in FIG. 2.

FIG. 12 is a cross-sectional view illustrating a step of a method of manufacturing a wiring device according to another embodiment.

FIG. 13 is a cross-sectional view illustrating a step of the method of manufacturing the wiring device according to the other embodiment, which is a subsequent step to FIG. 12.

FIG. 14 is a cross-sectional view illustrating a step of the method of manufacturing the wiring device according to the other embodiment, which is a subsequent step to FIG. 13.

FIG. 15 is a cross-sectional view illustrating a step of the method of manufacturing the wiring device according to the other embodiment, which is a subsequent step to FIG. 14.

FIG. 16 is a cross-sectional view illustrating a step of the method of manufacturing the wiring device according to the other embodiment, which is a subsequent step to FIG. 15.

FIG. 17 is a cross-sectional view illustrating a step of the method of manufacturing the wiring device according to the other embodiment, which is a subsequent step to FIG. 16.

FIG. 18 is a cross-sectional view illustrating a step of the method of manufacturing the wiring device according to the other embodiment, which is a subsequent step to FIG. 17.

FIG. 19 is a cross-sectional view illustrating a step of the method of manufacturing the wiring device according to the other embodiment, which is a subsequent step to FIG. 18.

FIG. 20 is a cross-sectional view illustrating a step of the method of manufacturing the wiring device according to the other embodiment, which is a subsequent step to FIG. 19.

FIG. 21 is a cross-sectional view illustrating a step of the method of manufacturing the wiring device according to the other embodiment, which is a subsequent step to FIG. 20.

FIG. 22 is a cross-sectional view illustrating a step of the method of manufacturing the wiring device according to the other embodiment, which is a subsequent step to FIG. 21.

FIG. 23 is a cross-sectional view illustrating a step of the method of manufacturing the wiring device according to the other embodiment, which is a subsequent step to FIG. 22.

FIG. 24 is a cross-sectional view illustrating a step of the method of manufacturing the wiring device according to the other embodiment, which is a subsequent step to FIG. 23.

FIG. 25 is a cross-sectional view illustrating a step of the method of manufacturing the wiring device according to the other embodiment, which is a subsequent step to FIG. 24.

FIG. 26 is a cross-sectional view illustrating a step of the method of manufacturing the wiring device according to the other embodiment, which is a subsequent step to FIG. 25.

FIG. 27 is a cross-sectional view illustrating a step of the method of manufacturing the wiring device according to the other embodiment, which is a subsequent step to FIG. 26.

FIG. 28 is a cross-sectional view illustrating a step of the method of manufacturing the wiring device according to the other embodiment, which is a subsequent step to FIG. 27.

FIG. 29 is a cross-sectional view illustrating a step of the method of manufacturing the wiring device according to the other embodiment, which is a subsequent step to FIG. 28.

FIG. 30 is a cross-sectional view illustrating a step of the method of manufacturing the wiring device according to the other embodiment, which is a subsequent step to FIG. 29.

FIG. 31 is a cross-sectional view illustrating a step of the method of manufacturing the wiring device according to the other embodiment, which is a subsequent step to FIG. 30.

FIG. 32 is a cross-sectional view illustrating a step of the method of manufacturing the wiring device according to the other embodiment, which is a subsequent step to FIG. 31.

FIG. 33 is a cross-sectional view illustrating a step of the method of manufacturing the wiring device according to the other embodiment, which is a subsequent step to FIG. 32.

FIG. 34 is a cross-sectional view illustrating a step of a method of manufacturing a semiconductor device according to one embodiment.

FIG. 35 is a cross-sectional view of a wiring device according to one embodiment.

FIG. 36 is an enlarged view of the wiring device illustrated in FIG. 35.

FIG. 37 is a cross-sectional view illustrating a wiring device according to another embodiment.

FIG. 38 is a plan view of the wiring device illustrated in FIG. 37.

FIG. 39 is a cross-sectional view illustrating a wiring device according to another embodiment.

FIG. 40 is a cross-sectional view illustrating a wiring device according to another embodiment.

FIG. 41 is a cross-sectional view of a semiconductor device according to one embodiment.

FIG. 42 is an enlarged view of the semiconductor device illustrated in FIG. 41.

### DETAILED DESCRIPTION

First, problems of the background arts will be described. A module using a chiplet integration technique requires a wiring chip for performing bridge connection between a plurality of chips. On the wiring chip, a wiring layer needs to be formed by stacking a plurality of layers of fine wiring. Examples of a method of manufacturing the wiring include a semi additive process (SAP) and a damascene process.

The SAP process is a manufacturing method in which a metal thin film serving as a seed layer for electrolytic plating is formed on a substrate, a resist layer having opening at a portion where wiring is to be formed, metal conductor wiring is formed at the opening by electrolytic plating, the resist layer is removed, and the seed layer remaining at portions other than the wiring portion is removed by etching.

The damascene process is a manufacturing method of forming and stacking fine wiring of a semiconductor chip, in which a groove is formed in an insulating layer generally made of an inorganic material and a metal conductor is embedded in the groove to form wiring.

Examples of a manufacturing method of planarization when performing the damascene process include a chemical mechanical polishing (CMP) process. The CMP process is a method that polishes and planarizes the surface of the wiring layer where the metal conductor has been embedded using a slurry or a chemical liquid as a polishing agent.

The CMP process requires expensive equipment, a slurry material, and a special chemical liquid. In addition, a large number of steps are required after polishing to remove the chemical liquid and treat the waste liquid.

In the SAP process, when the seed layer is removed by etching, the wiring is also etched at the same time, which may cause too thin wiring. For this reason, a risk of a broken wire increases in the case of fine wiring with a thickness of, for example, 2 μm.

Next, one aspect of the present invention will be described.

In the drawings of the embodiments, the same or similar parts are denoted by the same or similar symbols or reference numerals, and the description will not be repeated in principle.

In addition, in the accompanying drawings, hatching or the like may be omitted even in a cross section when the illustration becomes complicated or the object is clearly distinguished from a void space. In this regard, the outline of the background may be omitted even for a hole closed in a planar manner when it is obvious from the description or the like. Furthermore, even if it is not a cross section, hatching or a dot pattern may be added to clearly indicate that the object is not a void space or to clearly indicate the boundary of a region.

### <Method of Manufacturing Wiring Device>

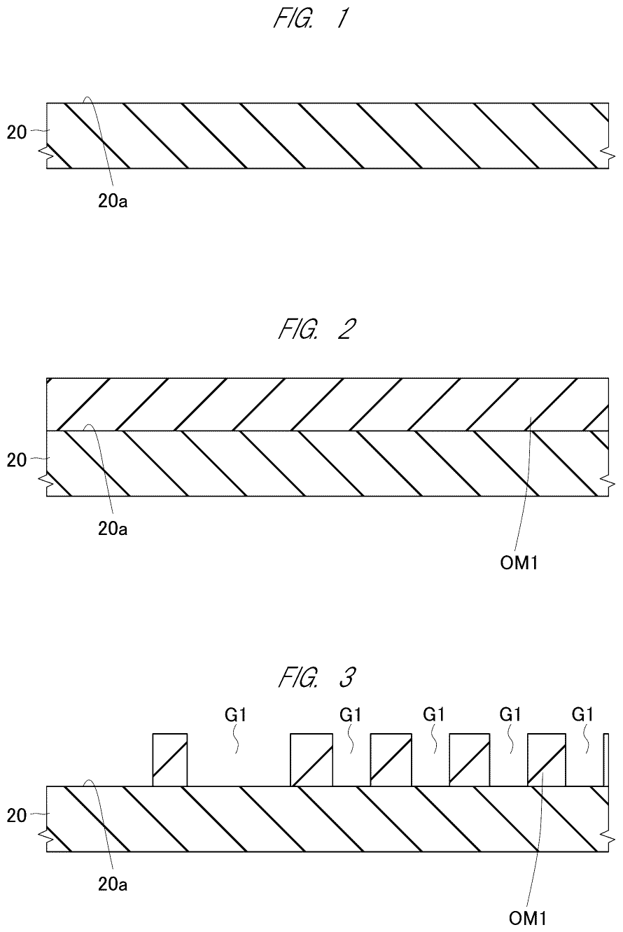

First, a method of manufacturing a wiring device according to one embodiment will be described. FIG. 1 is a cross-sectional view illustrating a step of the method of manufacturing the wiring device according to the one embodiment. As illustrated in FIG. 1, the method of manufacturing the wiring device according to the present embodiment includes a step of preparing a substrate 20. The substrate 20 has an upper surface 20a. The upper surface 20a of the substrate 20 is a flat surface. The surface roughness of the upper surface 20a of the substrate 20 is, for example, Ra 0.01 μm or more and Ra 0.05 μm or less. In plan view, the substrate 20 is circular. The substrate 20 is, for example, in a circular wafer shape. The substrate 20 is, for example, an inorganic substrate made of silicon or glass.

In the present embodiment, no electronic circuit such as a transistor circuit or an integrated circuit is formed on the substrate 20.

FIG. 2 is a cross-sectional view illustrating a step of the method of manufacturing the wiring device according to the one embodiment. As illustrated in FIG. 2, the method of manufacturing the wiring device according to the present embodiment includes a step of applying an organic insulating material OM1 onto the upper surface 20a of the substrate 20. The organic insulating material OM1 is applied onto the upper surface 20a of the substrate 20 using spin coating, for example. The thickness of the organic insulating material OM1 applied onto the upper surface 20a of the substrate 20 is, for example, 4 μm or more and 6 μm or less.

In the present embodiment, the organic insulating material OM1 is an insulating resin. Examples of the insulating resin include a photosensitive liquid insulating resin. The main component of the photosensitive liquid insulating resin is, for example, polybenzoxazole (PBO) or polyimide (PI), which is an organic material.

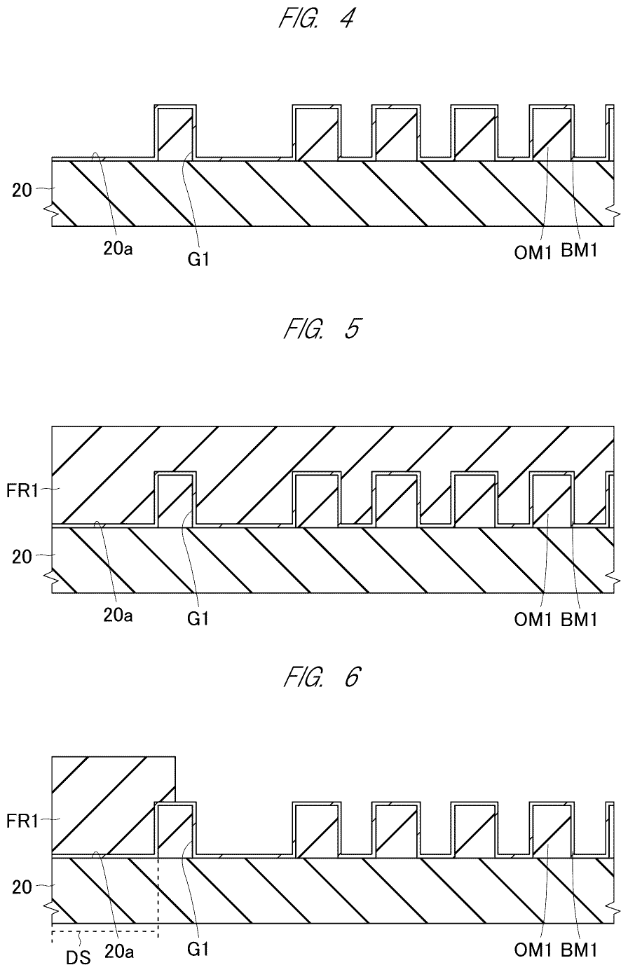

FIG. 3 is a cross-sectional view illustrating a step of the method of manufacturing the wiring device according to the one embodiment. As illustrated in FIG. 3, the method of manufacturing the wiring device according to the present embodiment includes a step of removing a part of the organic insulating material OM1 to form a groove portion G1. In the present embodiment, a part of the organic insulating material OM1 applied onto the upper surface 20a of the substrate 20 is removed.

Examples of the method of removing a part of the organic insulating material OM1 include patterning. Specifically, the organic insulating material OM1 that is a photosensitive liquid insulating resin is exposed by a stepper exposure machine using a photomask. Thereafter, the exposed organic insulating material OM1 is developed and cured to form the groove portion G1 serving as wiring in the organic insulating material OM1. In other words, a part of the organic insulating material OM1 is removed by the exposure processing and the development processing to form the groove portion G1. In the example illustrated in FIG. 3, a plurality of groove portions G1 is formed. As illustrated in FIG. 3, after a part of the organic insulating material OM1 is removed, the upper surface 20a of the substrate 20 is exposed from the groove portion G1. The groove portion G1 is a groove for providing wiring. The width of the groove portion G1 is, for example, 2 μm or less. In addition, the width of the organic insulating material OM1 sandwiched between the adjacent groove portions G1 is, for example, 2 μm or less.

FIG. 4 is a cross-sectional view illustrating a step of the method of manufacturing the wiring device according to the one embodiment. As illustrated in FIG. 4, the method of manufacturing the wiring device according to the present embodiment includes a step of forming a seed layer BM1 so as to cover the organic insulating material OM1. As illustrated in FIG. 4, the seed layer BM1 is formed after a part of the organic insulating material OM1 is removed. The seed layer BM1 is formed so as to cover the organic insulating material OM1 and the upper surface 20a of the substrate 20. The seed layer BM1 functions as a barrier metal. The step of forming the seed layer BM1 is not essential.

The seed layer BM1 is made of metal. Examples of the metal constituting the seed layer BM1 include at least one of Ti, Ni, and Cu. In addition, the seed layer BM1 is a single layer formed of any of a layer made of Ti, a layer made of Ni, and a layer made of Cu, or a layer obtained by stacking two or more of these layers. Examples of the method of forming the metal seed layer BM1 include sputtering. The thickness of the seed layer BM1 is, for example, 0.06 μm or less. When the seed layer BM1 includes the Ti layer, the thickness of the Ti layer is set to 0.03 μm or less. For example, a Ti thin film of 0.02 μm is formed by sputtering, and then Cu is sputtered onto the Ti film, which can form the seed layer BM1 with a thickness of 0.05 μm in total.

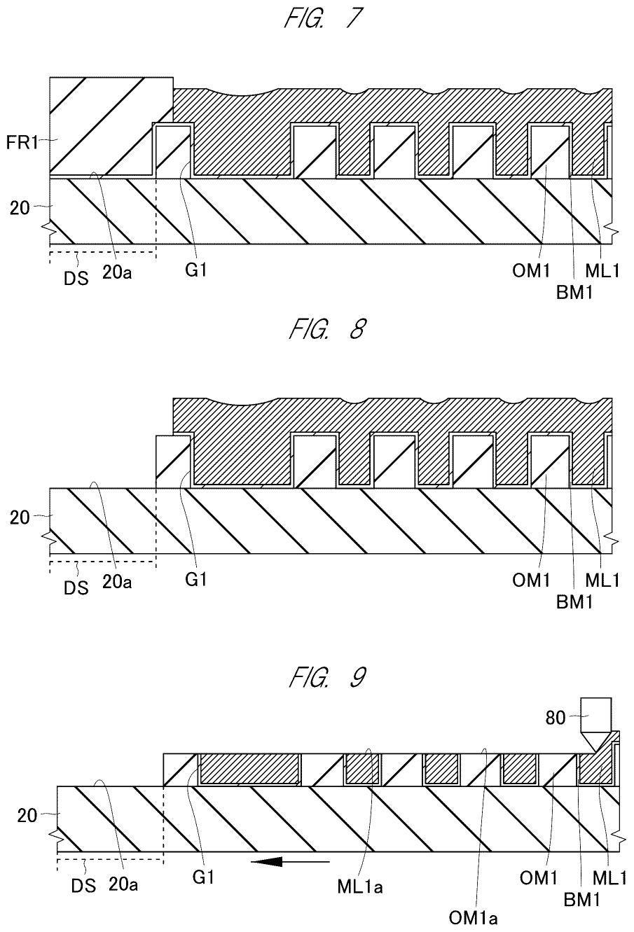

FIG. 5 is a cross-sectional view illustrating a step of the method of manufacturing the wiring device according to the one embodiment. As illustrated in FIG. 5, the method of manufacturing the wiring device according to the present embodiment includes a step of applying a resist FR1 so as to cover the organic insulating material OM1. The resist FR1 is applied so as to cover the organic insulating material OM1 and the upper surface 20a of the substrate 20. In the example illustrated in FIG. 5, the resist FR1 covers the organic insulating material OM1 and the upper surface 20a of the substrate 20 via the seed layer BM1. In the present embodiment, the resist FR1 is a photoresist. Examples of the method of applying the resist FR1 include spin coating.

FIG. 6 is a cross-sectional view illustrating a step of the method of manufacturing the wiring device according to the one embodiment. As illustrated in FIG. 6, the method of manufacturing the wiring device according to the present embodiment includes a step of removing a part of the resist FR1 to expose the groove portion G1 of the organic insulating material OM1. After a part of the resist FR1 is removed, the resist FR1 covers the upper surface 20a of the substrate 20 serving as a dicing street DS. As illustrated in FIG. 6, the dicing street DS is a part of the upper surface 20a of the substrate 20. After a part of the resist FR1 is removed, the groove portion G1 of the organic insulating material OM1 is exposed from the resist FR1. Examples of the method of removing the resist FR1 include patterning.

FIG. 7 is a cross-sectional view illustrating a step of the method of manufacturing the wiring device according to the one embodiment. As illustrated in FIG. 7, the method of manufacturing the wiring device according to the present embodiment includes a step of forming a conductor layer ML1 so as to fill the groove portion G1 of the organic insulating material OM1. The height of the formed conductor layer ML1 is larger than the height of the organic insulating material OM1. A difference between the height of the conductor layer ML1 and the height of the organic insulating material OM1 is, for example, 1 μm or more and 10 μm or less. In the present embodiment, the height of the conductor layer ML1 is a height from the upper surface 20a of the substrate 20. As illustrated in FIG. 7, the conductor layer ML1 is formed so as to cover the organic insulating material OM1. In addition, the height of the formed conductor layer ML1 is smaller than the height of the resist FR1.

Examples of the method of forming the conductor layer ML1 include electrolytic plating. In the example illustrated in FIG. 7, the seed layer BM1 is used as a seed layer for electrolytic plating. The metal constituting the conductor layer ML1 is, for example, Cu.

FIG. 8 is a cross-sectional view illustrating a step of the method of manufacturing the wiring device according to the one embodiment. As illustrated in FIG. 8, the method of manufacturing the wiring device according to the present embodiment includes a step of removing the resist FR1 to expose the upper surface 20a of the substrate 20. The resist FR1 covering the upper surface 20a of the substrate 20 serving as the dicing street DS is removed. As a result, the resist FR1 is entirely removed. Examples of the method of removing the resist FR1 include a method using a peeling agent.

Even after the resist FR1 is removed, the upper surface 20a of the substrate 20 serving as the dicing street DS is covered with the seed layer BM1. Therefore, the seed layer BM1 exposed by removing the resist FR1 is removed. After the seed layer BM1 is removed, the upper surface 20a of the substrate 20 serving as the dicing street DS is exposed from the organic insulating material OM1, the conductor layer ML1, and the seed layer BM1. Examples of the method of removing the seed layer BM1 include etching.

FIG. 9 is a cross-sectional view illustrating a step of the method of manufacturing the wiring device according to the one embodiment. FIG. 9 illustrates a state where machining using a cutting blade 80 is in process. In addition, in FIG. 9, an example of a direction in which the substrate 20 is moved is schematically illustrated by an arrow. As illustrated in FIG. 9, the method of manufacturing the wiring device according to the present embodiment includes a step of machining a part of the conductor layer ML1 and a part of the organic insulating material OM1 using the cutting blade 80. The conductor layer ML1 remaining after machining serves as wiring. In addition, the organic insulating material OM1 remaining after machining serves as an organic insulating layer for insulating the wirings from each other.

Examples of the machining method include planer cutting. Planer cutting is one of machining methods in which the cutting blade 80 and the substrate 20 are brought into contact with each other while either of them is linearly moved to perform machining using the cutting blade 80 that is not a rotary blade. Specifically, planer cutting includes the following four methods. In the first method, machining is performed by bringing the substrate 20 into contact with the cutting blade 80 that is in a fixed position while linearly moving the substrate 20. In the second method, machining is performed by bringing the cutting blade 80 into contact with the substrate 20 that is in a fixed position while linearly moving the cutting blade 80. In the third method, machining is performed by bringing the substrate 20 into contact with the cutting blade 80 that is in a fixed position while rotating the substrate 20. In the fourth method, machining is performed by linearly moving and bringing the substrate 20 into the cutting blade 80 that is fixed to a turntable larger than the substrate 20, while the turntable is rotated. In the fourth method, machining is performed while the cutting blade 80 is following a circular path. However, in each region of the substrate 20 where the wiring device is formed, it can be said that a curve close to a straight line is machined.

By machining, the organic insulating material OM1 covered with the conductor layer ML1 is exposed. After machining, the height of the organic insulating material OM1 is, for example, 2 μm or less. In addition, after machining, the height from the upper surface 20a of the substrate 20 to an upper surface ML1a of the conductor layer ML1 is, for example, 2 μm or less. By machining, the upper surface ML1a of the conductor layer ML1 and an upper surface OM1a of the organic insulating material OM1 are planarized. After machining, the upper surface OM1a of the organic insulating material OM1 and the upper surface ML1a of the conductor layer ML1 are located on the same plane. In addition, after machining, the surface roughness of the surface including the upper surface OM1a of the organic insulating material OM1 and the upper surface ML1a of the conductor layer ML1 is, for example, Ra 0.01 μm or more and Ra 0.05 μm or less.

When a part of the seed layer BM1 is removed by machining, the organic insulating material OM1 is exposed. As a result, the upper surface OM1a of the organic insulating material OM1, the upper surface ML1a of the conductor layer ML1, and an exposed surface of the seed layer BM1 are located on the same plane. In addition, after machining, the surface roughness of the surface including the upper surface OM1a of the organic insulating material OM1, the upper surface ML1a of the conductor layer ML1, and the exposed surface of the seed layer BM1 is, for example, Ra 0.01 μm or more and Ra 0.05 μm or less.

Incidentally, methods for machining a part of the conductor layer ML1 and a part of the organic insulating material OM1 include performing machining by pressing the cutting blade against a workpiece while rotating the cutting blade. Such a machining method is called fly cutting or milling, and is different from the machining method of the present embodiment in that the cutting blade is rotated. When machining is performed by milling, a rough machining trace like continuous circles is formed due to the rotating cutting blade.

When the cutting blade is pressed against and brought into contact with the workpiece while being rotated, the cutting resistance increases. Furthermore, since high heat is also generated, residual stress remaining on the workpiece increases, which causes warpage and distortion. On the other hand, according to the present embodiment, machining is performed by bringing the cutting blade 80 and the substrate 20 into contact with each other through linear movement without rotating the cutting blade 80 itself. In this case, the residual stress value of the workpiece can be reduced. As a result, warpage deformation or distortion of the substrate 20 after machining can be suppressed.

Chipping generated by planer cutting are in a state of so-called curls of wood. Therefore, chipping are removed more easily than a slurry or special chemical liquid remaining on the surface of the wiring device when the CMP process is used. In addition, since the size of chipping itself is large, chipping are less likely to be accumulated even when grinding is performed while the upper surface 20a of the substrate 20 serving as the dicing street DS is exposed.

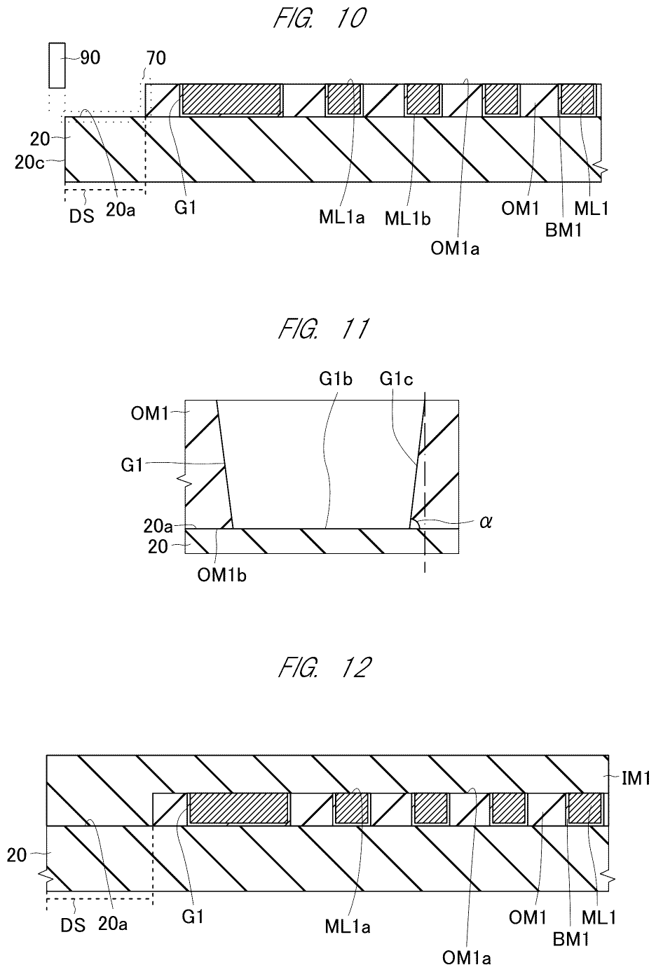

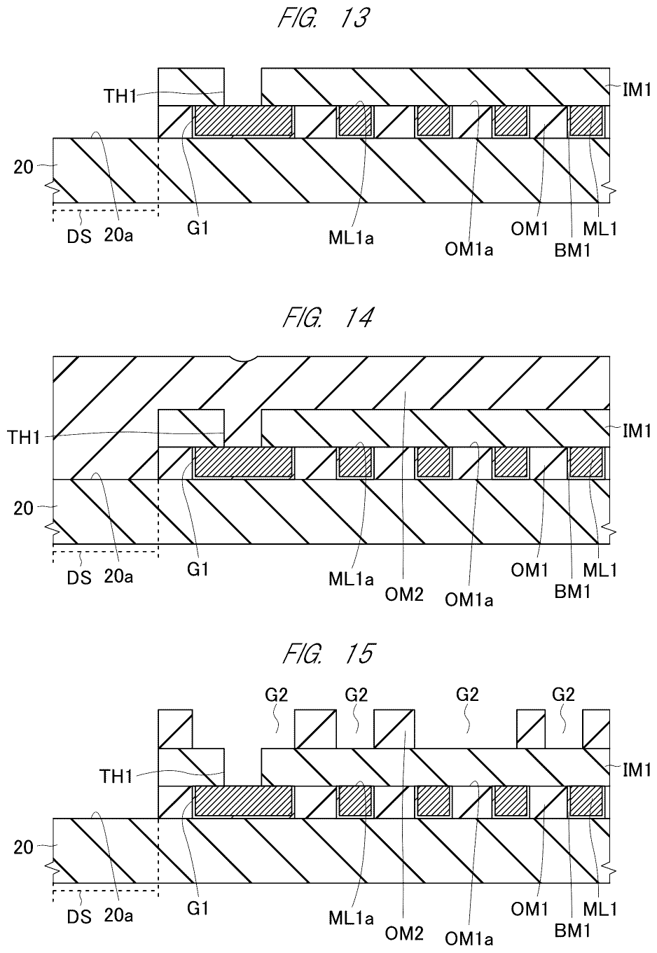

FIG. 10 is a cross-sectional view illustrating a step of the method of manufacturing the wiring device according to the one embodiment. As illustrated in FIG. 10, the method of manufacturing the wiring device according to the present embodiment includes a step of cutting the dicing street DS that is a portion where the upper surface 20a of the substrate 20 is exposed. By cutting the dicing street DS, the wiring device can be singulated. In the example illustrated in FIG. 10, a blade 90 is used to perform cutting.

As illustrated in FIG. 10, a part of the dicing street DS remains even after cutting. That is, a part of the portion where the upper surface 20a of the substrate 20 is exposed from the conductor layer ML1, the organic insulating material OM1, and the seed layer BM1 remains. After cutting, a side surface 20c of the substrate 20 is formed. After cutting, a step portion 70 including the substrate 20 and the organic insulating material OM1 is formed.

Next, effects of the method of manufacturing the wiring device according to the present embodiment will be described. The method of manufacturing the wiring device according to the present embodiment includes the step of cutting the portion where the upper surface 20a of the substrate 20 is exposed. In addition, even after cutting, a part of the upper surface 20a of the substrate 20 remains uncut. As a result, the step portion 70 including the substrate 20 and the organic insulating material OM1 is formed. Therefore, when the wiring device is sealed with a sealing body such as resin, the contact area between the sealing body and the wiring device can be increased. As a result, the sealing body and the wiring device can be strongly bonded. This can improve the mounting reliability of the wiring device.

In addition, since the portion where the upper surface 20a of the substrate 20 is exposed is cut, the blade 90 does not cut the conductor layer ML1 and the seed layer BM1 during cutting. Since the metal portion is not cut, cutting is easier and the stress applied to the substrate 20 is small. In addition, since fine metal powder due to dicing of the metal portion is not generated, the cutting force is less likely to be reduced due to adhering of the metal powder to the blade 90.

The method of manufacturing the wiring device according to the present embodiment planarizes the upper surface ML1a of the conductor layer ML1 and the upper surface OM1a of the organic insulating material OM1 by machining a part of the conductor layer ML1 and a part of the organic insulating material OM1 using the cutting blade 80. Thus, the upper surface ML1a of the conductor layer ML1 and the upper surface OM1a of the organic insulating material OM1 are substantially on the same plane and are flat. As a result, when wiring is further formed on the conductor layer ML1 and the organic insulating material OM1, the variation in the thickness of the wiring formed above can be reduced. Consequently, a broken wire can be prevented even when the wiring formed above is thin.

As described first, it is conceivable to use CMP to planarize the organic insulating material OM1 and the conductor layer ML1. However, CMP requires expensive equipment, slurry materials, and management of complex processing conditions.

In the method of manufacturing the wiring device according to the present embodiment, the conductor layer ML1 and the organic insulating material OM1 are partially removed and planarized by machining. Therefore, there is no need for CMP, which requires expensive materials and equipment, and complicated processes and processing conditions. As a result, the planarization process can be performed at low cost.

Next, another effect of the method of manufacturing the wiring device according to the present embodiment will be described. In the SAP process, a metal thin film serving as the seed layer BM1 is provided in the wiring portion. The excess seed layer BM1 is removed by an etching process while the resist FR1 is removed and the wiring is exposed. However, since the wiring is also dissolved under the influence of the etching process, the risk that a broken wire occurs increases.

On the other hand, in the method of manufacturing the wiring device according to the present embodiment, a part of the seed layer BM1 is removed using the cutting blade 80 to insulate adjacent conductor layers ML1 from each other. In addition, when the seed layer BM1 on the dicing street DS is removed by etching, the side surface of the conductor layer ML1 is sealed with the organic insulating material OM1. Therefore, the etching process is less likely to influence the conductor layer ML1 serving as wiring. As a result, a broken wire due to the etching process is less likely to occur even in the case of thin wiring with a thickness of, for example, 2 μm or less.

Next, modifications of the method of manufacturing the wiring device according to the present embodiment and effects thereof will be described.

In the method of manufacturing the wiring device according to the present embodiment, it is preferable that the substrate 20 is not provided with an electronic circuit.

For a substrate on which wiring is provided, a wafer on which a transistor circuit and an integrated circuit are formed for a semiconductor chip may be used. However, the surface of the semiconductor chip has a step because an electrode and a polyimide layer are formed on the chip. For this reason, when a wiring layer is formed by stacking fine wiring on the surface of the semiconductor chip, the lower surface of the insulating layer formed immediately above the semiconductor chip may not be flat. Therefore, the insulating layer is also likely to have variations in thickness. This may cause a problem when a thin insulating layer or wiring layer is processed.

In the method of manufacturing the wiring device according to the present embodiment, since the substrate 20 is not provided with an electronic circuit, the upper surface 20a of the substrate 20 can be a flat surface. Therefore, variations in the thicknesses of the organic insulating material OM1 and the conductor layer ML1 can be further reduced.

The thickness of the seed layer BM1 is preferably 0.06 μm or less. In addition, when the seed layer BM1 includes the Ti layer, the thickness of the Ti layer is preferably 0.03 μm or less. As a result, the load on the cutting blade 80 is reduced, and wear can be suppressed.

FIG. 11 is an enlarged view of the groove portion of the organic insulating material illustrated in FIG. 2. As illustrated in FIG. 11, a side wall G1c of the groove portion G1 of the organic insulating material OM1 is preferably tapered. The width of the groove portion G1 increases with an increase in the distance from the upper surface 20a of the substrate 20. An angle α formed by the side wall G1c of the groove portion G1 and a bottom portion OM1b of the organic insulating material OM1 is preferably 80° or more and less than 90°.

If the side wall G1c of the groove portion G1 is perpendicular to the upper surface 20a of the substrate 20, the side wall G1c that is a perpendicular portion of the groove portion G1 may be less likely to be coated with a film than a plane portion G1b of the groove portion G1. For example, when the seed layer BM1 is formed by sputtering, the seed layer BM1 of the side wall G1c that is the perpendicular portion of the groove portion G1 may have a smaller thickness than the plane portion G1b of the groove portion G1. Therefore, in order to form the seed layer BM1 with a necessary thickness on both the plane portion G1b of the groove portion G1 and the side wall G1c of the groove portion G1, the seed layer BM1 needs to be formed to be thick to some extent.

However, when machining is performed using a hard metal such as Ti as the seed layer BM1, a load on the cutting blade 80 may increase if the thickness of the seed layer BM1 is large. This makes machining difficult, which may shorten the life of the cutting blade 80.

In a case where the angle x formed by the side wall G1c of the groove portion G1 and the bottom portion OM1b of the organic insulating material OM1 is less than 90°, when the seed layer BM1 is formed by the sputtering process, the side wall G1c of the groove portion G1 is easily coated with a film, and thus the seed layer BM1 with a necessary thickness can be formed to be thin. In a case where the angle α formed by the side wall G1c of the groove portion G1 and the bottom portion OM1b of the organic insulating material OM1 is 80° or more, a dimensional difference between the widths of the upper portion and the lower portion of the wiring formed in the groove portion G1 can be reduced.

In the method of manufacturing the wiring device according to the present embodiment, the thickness of the organic insulating material OM1 after machining is preferably 2 μm or less. In addition, the height from the upper surface 20a of the substrate 20 to the upper surface ML1a of the conductor layer ML1 is preferably 2 μm or less. As a result, even when the width of the conductor layer ML1 serving as wiring is 2 μm or less, the aspect ratio of the wiring can be set to 1 or less.

In addition, in a case where the side wall G1c of the groove portion G1 of the organic insulating material OM1 is tapered, the dimensional difference between the widths of the upper surface ML1a and a lower surface ML1b of the conductor layer ML1 may increase with an increase in the thickness of the conductor layer ML1 embedded in the groove portion. When the height from the upper surface 20a of the substrate 20 to the upper surface ML1a of the conductor layer ML1 is 2 μm or less, the dimensional difference between the widths of the upper surface ML1a and the lower surface ML1b of the conductor layer ML1 can be reduced even if the side wall G1c of the groove portion G1 of the organic insulating material OM1 is tapered. In addition, even when an interval between the adjacent grooves G1 of the organic insulating material OM1 is set to 2 μm or less in order to shorten the wiring interval, a dimensional difference between the upper and lower widths of the organic insulating material OM1 between the adjacent grooves G1 can be reduced. As a result, highly accurate wiring can be formed.

Although the present embodiment exemplifies the method that uses a liquid resin for the organic insulating material OM1 and applies the liquid by spin coating, the embodiment can b modified to a method that uses a film-shaped material for the organic insulating material OM1 and laminates the material. In this case, even when there is a recess or unevenness such as a via hole in a portion where the organic insulating material OM1 is to be formed, the organic insulating material OM1 can be formed to be flat. In addition, when a necessary thickness is to be secured, the effect of easily securing the thickness can be expected more from the film-shaped material. Furthermore, the liquid material and the film material can also be combined.

Next, a method of manufacturing a wiring device according to another embodiment will be described. The method of manufacturing the wiring device according to the other embodiment is the same as the method of manufacturing the wiring device illustrated in FIGS. 1 to 9.

FIG. 12 is a cross-sectional view illustrating a step of the method of manufacturing the wiring device according to the other embodiment. As illustrated in FIG. 12, after the machining step illustrated in FIG. 9, a step of applying an interlayer organic insulating material IM1 onto the conductor layer ML1 and the organic insulating material OM1 is provided. The interlayer organic insulating material IM1 is applied so as to cover the conductor layer ML1, the organic insulating material OM1, the seed layer BM1, and the upper surface 20a of the substrate 20. The interlayer organic insulating material IM1 is applied using spin coating, for example. The height of the applied interlayer organic insulating material IM1 from the upper surface OM1a of the organic insulating material OM1 is, for example, 4 μm or more and 6 μm or less.

In the present embodiment, the interlayer organic insulating material IM1 is an insulating resin. Examples of the insulating resin include a photosensitive liquid insulating resin. The main component of the photosensitive liquid insulating resin is, for example, polybenzoxazole (PBO) or polyimide (PI), which is an organic material. For the interlayer organic insulating material IM1, the same material as the above-described organic insulating material OM1 can be used.

FIG. 13 is a cross-sectional view illustrating a step of the method of manufacturing the wiring device according to the other embodiment. As illustrated in FIG. 13, the method of manufacturing the wiring device according to the other embodiment includes a step of removing a part of the interlayer organic insulating material IM1 to form a through portion TH1. A part of the interlayer organic insulating material IM1 is removed such that the conductor layer ML1 is exposed from the through portion TH1. A part of the interlayer organic insulating material IM1 is removed such that the upper surface 20a of the substrate 20 is exposed from the interlayer organic insulating material IM1. As illustrated in FIG. 13, after a part of the interlayer organic insulating material IM1 is removed, a part of the conductor layer ML1 is exposed from the interlayer organic insulating material IM1, and a part of the conductor layer ML1 is covered with the interlayer organic insulating material IM1. Examples of the method of removing a part of the interlayer organic insulating material IM1 include patterning.

FIG. 14 is a cross-sectional view illustrating a step of the method of manufacturing the wiring device according to the other embodiment. As illustrated in FIG. 14 the method of manufacturing the wiring device according to the other embodiment includes a step of applying an organic insulating material OM2 so as to cover the interlayer organic insulating material IM1. As illustrated in FIG. 14, the organic insulating material OM2 is applied so as to cover the interlayer organic insulating material IM1, the conductor layer ML1, and the upper surface 20a of the substrate 20. In the example illustrated in FIG. 14, the organic insulating material OM2 is applied so as to fill the through portion TH1. The organic insulating material OM2 is applied using spin coating, for example. The height of the applied organic insulating material OM2 from the upper portion of the interlayer organic insulating material IM1 is, for example, 4 μm or more and 6 μm or less. For the organic insulating material OM2, the same material as the interlayer organic insulating material IM1 can be used.

FIG. 15 is a cross-sectional view illustrating a step of the method of manufacturing the wiring device according to the other embodiment. As illustrated in FIG. 15, the method of manufacturing the wiring device according to the other embodiment includes a step of removing a part of the organic insulating material OM2 such that the through portion TH1 of the interlayer organic insulating material IM1 is exposed from the organic insulating material OM2 to form a groove portion G2. As illustrated in FIG. 15, a plurality of groove portions G2 is formed.

As illustrated in FIG. 15, after a part of the organic insulating material OM2 is removed, the through portion TH1 of the interlayer organic insulating material IM1 communicates with the groove portion G2 of the organic insulating material OM2. In addition, after a part of the organic insulating material OM2 is removed, the interlayer organic insulating material IM1 is exposed from the groove portion G2 of the organic insulating material OM2. In addition, after a part of the organic insulating material OM2 is removed, the upper surface 20a of the substrate 20 is exposed from the organic insulating material OM2. For the method of removing a part of the organic insulating material OM2, the same method as the method of removing a part of the interlayer organic insulating material IM1 can be used.

FIG. 16 is a cross-sectional view illustrating a step of the method of manufacturing the wiring device according to the other embodiment. As illustrated in FIG. 16, the method of manufacturing the wiring device according to the other embodiment includes a step of forming a seed layer BM2 so as to cover the conductor layer ML1, the interlayer organic insulating material IM1, and the organic insulating material OM2. As illustrated in FIG. 16, the seed layer BM2 is formed so as to cover the upper surface 20a of the substrate 20. The seed layer BM2 functions as a barrier metal. The seed layer BM2 is formed so as to cover the organic insulating material OM2, the interlayer organic insulating material IM1 exposed from the organic insulating material OM2, and the conductor layer ML1 exposed from the interlayer organic insulating material IM1. The step of forming the seed layer BM2 is not essential. The seed layer BM2 can be formed by the same method as that used for the seed layer BM1.

FIG. 17 is a cross-sectional view illustrating a step of the method of manufacturing the wiring device according to the other embodiment. As illustrated in FIG. 17, the method of manufacturing the wiring device according to the other embodiment includes a step of applying a resist FR2 so as to cover the organic insulating material OM2. The resist FR2 is applied so as to cover the organic insulating material OM2 and the upper surface 20a of the substrate 20. In the example illustrated in FIG. 17, the resist FR2 covers the organic insulating material OM2 and the upper surface 20a of the substrate 20 via the seed layer BM2. In the present embodiment, the resist FR2 is photoresist. Examples of the method of applying the resist FR2 include spin coating.

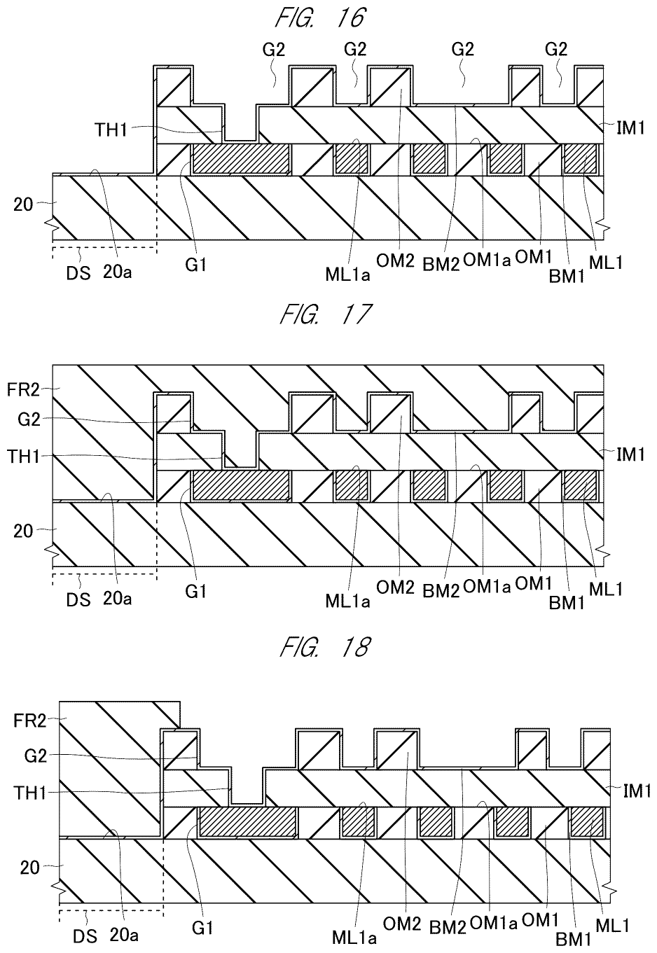

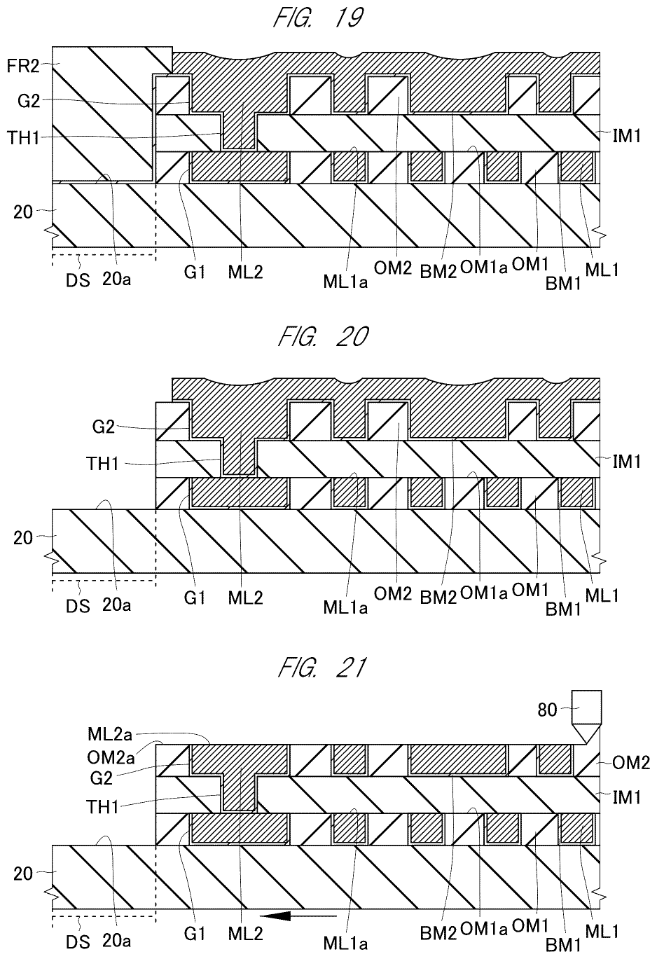

FIG. 18 is a cross-sectional view illustrating a step of the method of manufacturing the wiring device according to the other embodiment. As illustrated in FIG. 18, the method of manufacturing the wiring device according to the other embodiment includes a step of removing a part of the resist FR2 to expose the through portion TH1 of the interlayer organic insulating material IM1 and the groove portion G2 of the organic insulating material OM2. A part of the resist FR2 is removed so as to leave the resist FR2 covering the upper surface 20a of the substrate 20 serving as the dicing street DS. That is, after a part of the resist FR2 is removed, the resist FR2 covers the upper surface 20a of the substrate 20 serving as the dicing street DS. In addition, after a part of the resist FR2 is removed, the through portion TH1 of the interlayer organic insulating material IM1 and the groove portion G2 of the organic insulating material OM2 are exposed from the resist FR2. In the example illustrated in FIG. 18, since the seed layer BM2 is provided on the upper surface 20a of the substrate 20, after a part of the resist FR2 is removed, the resist FR2 covers the upper surface 20a of the substrate 20 via the seed layer BM2. Examples of the method of removing the resist FR2 include patterning.

FIG. 19 is a cross-sectional view illustrating a step of the method of manufacturing the wiring device according to the other embodiment. As illustrated in FIG. 19, the method of manufacturing the wiring device according to the other embodiment includes a step of forming a conductor layer ML2 so as to fill the through portion TH1 of the interlayer organic insulating material IM1 and the groove portion G2 of the organic insulating material OM2. The height of the formed conductor layer ML2 is larger than the height of the organic insulating material OM2. A difference between the height of the conductor layer ML2 and the height of the organic insulating material OM2 is, for example, 1 μm or more and 10 μm or less. In the present embodiment, the height of the conductor layer ML2 is a height from the upper surface 20a of the substrate 20. The height of the organic insulating material OM2 is a height from the upper surface 20a of the substrate 20. As illustrated in FIG. 19, the conductor layer ML2 is formed so as to cover the organic insulating material OM2. In addition, the height of the formed conductor layer ML2 is smaller than the height of the resist FR2. The height of the resist FR2 is a height from the upper surface 20a of the substrate 20.

Since the conductor layer ML1 is exposed from the through portion TH1 of the interlayer organic insulating material IM1 and the groove portion G2 of the organic insulating material OM2, the conductor layer ML2 is electrically connected to the conductor layer ML1. In the example illustrated in FIG. 19, since the seed layer BM2 is provided, the conductor layer ML2 is electrically connected to the conductor layer ML1 via the seed layer BM2.

Examples of a method of forming the conductor layer ML2 include electrolytic plating. In the example illustrated in FIG. 19, since the seed layer BM2 is provided, electrolytic plating is performed using the seed layer BM2 as a seed layer for electrolytic plating. The metal constituting the conductor layer ML2 is, for example, Cu.

FIG. 20 is a cross-sectional view illustrating a step of the method of manufacturing the wiring device according to the embodiment. As illustrated in FIG. 20, the method of other manufacturing the wiring device according to the other embodiment includes a step of removing the resist FR2 to expose the upper surface 20a of the substrate 20. The resist FR2 covering the upper surface 20a of the substrate 20 serving as the dicing street DS is removed. As a result, the resist FR2 is entirely removed. Examples of the method of removing the resist FR2 include a method using a peeling agent.

In the present embodiment, since the seed layer BM2 is formed, the upper surface 20a of the substrate 20 serving as the dicing street DS is covered with the seed layer BM2 even after the resist FR2 is removed. Therefore, after the resist FR2 is removed, the seed layer BM2 is removed such that the upper surface 20a of the substrate 20 serving as the dicing street DS is exposed. Examples of the method of removing the seed layer BM2 include etching.

FIG. 21 is a cross-sectional view illustrating a step of the method of manufacturing the wiring device according to the other embodiment. As illustrated in FIG. 21, the method of manufacturing the wiring device according to the other embodiment includes a step of machining a part of the conductor layer ML2 and a part of the organic insulating material OM2 using the cutting blade 80. The conductor layer ML2 remaining after machining serves as wiring. In addition, the organic insulating material OM2 remaining after machining serves as an organic insulating layer for insulating the wirings from each other.

Examples of the machining method include planer cutting. For planer cutting, the same method as that used in FIG. 9 can be used.

By machining, the organic insulating material OM2 covered with the conductor layer ML2 is exposed. After machining, the thickness of the organic insulating material OM2 is, for example, 2 μm or less. In addition, after machining, the height from the upper portion of the interlayer organic insulating material IM1 to an upper surface ML2a of the conductor layer ML2 is, for example, 2 μm or less. By machining, the upper surface ML2a of the conductor layer ML2 and an upper surface OM2a of the organic insulating material OM2 are planarized. After machining, the upper surface OM2a of the organic insulating material OM2 and the upper surface ML2a of the conductor layer ML2 are located on the same plane. In addition, after machining, the surface roughness of the surface including the upper surface OM2a of the organic insulating material OM2 and the upper surface ML2a of the conductor layer ML2 is, for example, Ra 0.01 μm or more and Ra 0.05 μm or less.

In the present embodiment, since the seed layer BM2 is provided, a part of the seed layer BM2 is machined, and the organic insulating material OM2 is exposed. After machining, the upper surface OM2a of the organic insulating material OM2, the upper surface ML2a of the conductor layer ML2, and an exposed surface of the seed layer BM2 are located on the same plane. In addition, after machining, the surface roughness of the surface including the upper surface OM2a of the organic insulating material OM2, the upper surface ML2a of the conductor layer ML2, and the exposed surface of the seed layer BM2 is, for example, Ra 0.01 μm or more and Ra 0.05 μm or less.

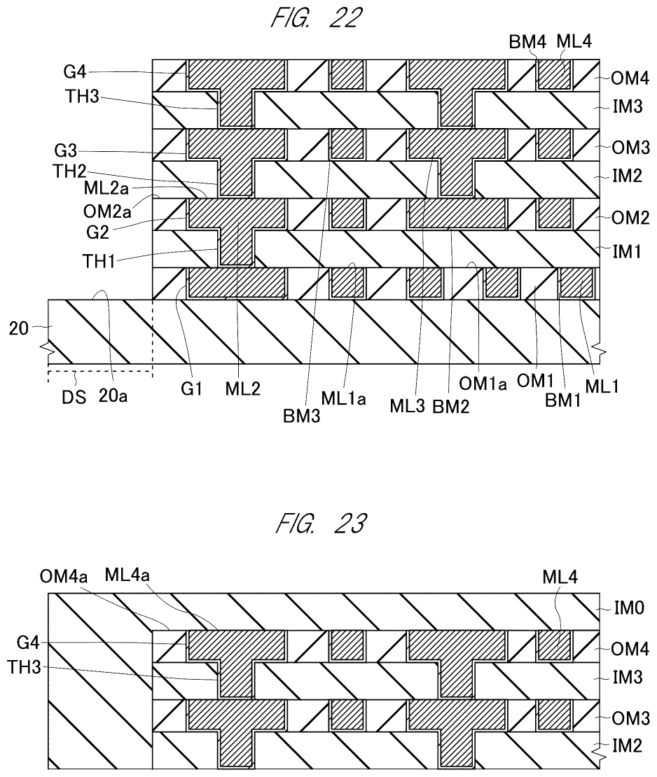

FIG. 22 is a cross-sectional view illustrating a step of the method of manufacturing the wiring device according to the other embodiment. FIG. 22 illustrates the wiring device after the steps of FIGS. 12 to 21 are repeated and additional two wiring layers are formed. An interlayer organic insulating material IM2, an organic insulating material OM3, an interlayer organic insulating material IM3, and an organic insulating material OM4 are sequentially formed on the organic insulating material OM2. A through portion TH2 is formed in the interlayer organic insulating material IM2. A groove portion G3 is formed in the organic insulating material OM3. A conductor layer ML3 is embedded in the through portion TH2 and the groove portion G3. The conductor layer ML3 is electrically connected to the conductor layer ML2 via a seed layer BM3. In addition, a through portion TH3 is formed in the interlayer organic insulating material IM3. A groove portion G4 is formed in the organic insulating material OM4. A conductor layer ML4 is embedded in the through portion TH3 and the groove portion G4. The conductor layer ML4 is electrically connected to the conductor layer ML3 via a seed layer BM4.

FIG. 23 is a cross-sectional view illustrating a step of the method of manufacturing the wiring device according to the other embodiment. FIG. 23 illustrates a step subsequent to FIG. 22. FIGS. 23 to 31 illustrate only a portion above the interlayer organic insulating material IM2 illustrated in FIG. 22. As illustrated in FIG. 23, the method of manufacturing the wiring device according to the other embodiment includes a step of applying an under-electrode insulating material IM0 onto the organic insulating material OM4. The under-electrode insulating material IM0 is applied so as to cover an upper surface OM4a of the organic insulating material OM4 and an upper surface ML4a of the conductor layer ML4. Although not illustrated in FIG. 23, the under-electrode insulating material IM0 is applied so as to cover the upper surface 20a of the substrate 20.

The under-electrode insulating material IM0 is an organic material. For the under-electrode insulating material IM0, the same material as the organic insulating material OM2 can be used. For the method of applying the under-electrode insulating material IM0, the same method as the method of applying the organic insulating material OM2 can be used. The height of the applied under-electrode insulating material IM0 from the upper surface OM4a of the organic insulating material OM4 is, for example, 4 μm or more and 6 μm or less.

FIG. 24 is a cross-sectional view illustrating a step of the method of manufacturing the wiring device according to the other embodiment. As illustrated in FIG. 24, the method of manufacturing the wiring device according to the other embodiment includes a step of removing a part of the under-electrode insulating material IM0 to form a through portion TH0. The through portion TH0 is formed in the under-electrode insulating material IM0 such that the conductor layer ML4 is exposed. In addition, although not illustrated in FIG. 24, a part of the under-electrode insulating material IM0 is removed such that the upper surface 20a of the substrate 20 is exposed from the under-electrode insulating material IM0. For the method of removing a part of the under-electrode insulating material IM0, the same method as the method of removing a part of the organic insulating material OM2 can be used. The diameter of the through portion TH0 is, for example, 5 μm or more and 35 μm or less. The diameter of the through portion TH0 is, for example, 10 μm.

FIG. 25 is a cross-sectional view illustrating a step of the method of manufacturing the wiring device according to the other embodiment. As illustrated in FIG. 25, the method of manufacturing the wiring device according to the other embodiment includes a step of forming a seed layer BM0 so as to cover the conductor layer ML4 and the under-electrode insulating material IM0. Although not illustrated in FIG. 25, the seed layer BM0 is formed so as to cover the upper surface 20a of the substrate 20. The step of forming the seed layer BM0 is not essential.

For the seed layer BM0, the same material as the seed layer BM2 can be used. For the method of forming the seed layer BM0, the same method as the method of forming the seed layer BM2 can be used.

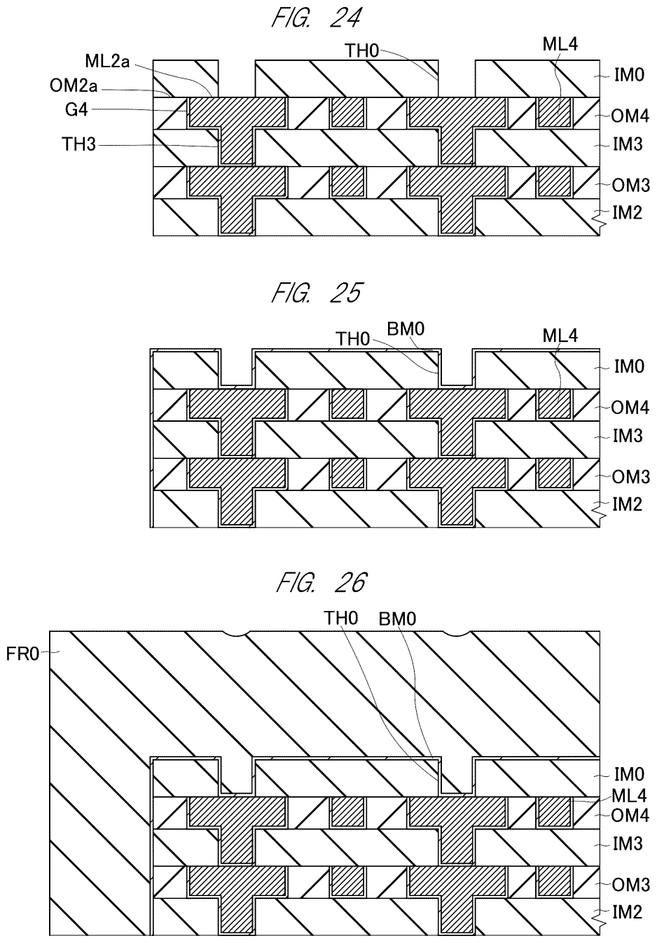

FIG. 26 is a cross-sectional view illustrating a step of the method of manufacturing the wiring device according to the other embodiment. As illustrated in FIG. 26, the method of manufacturing the wiring device according to the other embodiment includes a step of applying a resist FR0 so as to cover the under-electrode insulating material IM0. Although not illustrated in FIG. 26, the resist FR0 is applied so as to cover the upper surface 20a of the substrate 20. In the example illustrated in FIG. 26, the resist FR0 covers the under-electrode insulating material IM0 and the upper surface 20a of the substrate 20 via the seed layer BM0. In the present embodiment, the resist FR0 is a photoresist.

Examples of the method of applying the resist FR0 include spin coating.

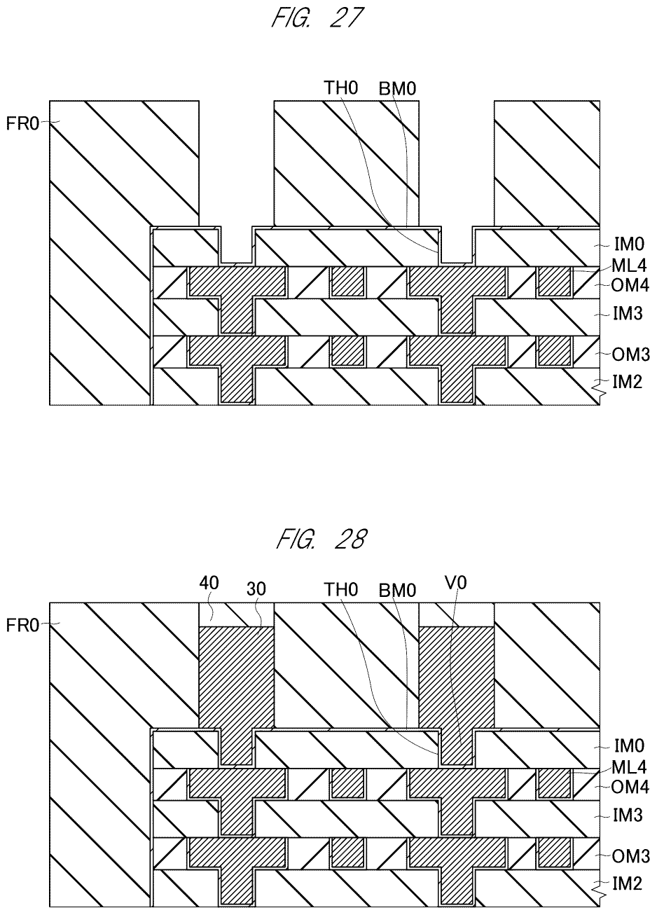

FIG. 27 is a cross-sectional view illustrating a step of the method of manufacturing the wiring device according to the other embodiment. As illustrated in FIG. 27, the method of manufacturing the wiring device according to the other embodiment includes a step of removing a part of the resist FR0 to expose the through portion TH0 of the under-electrode insulating material IM0. In the example illustrated in FIG. 27, after a part of the resist FR0 is removed, a cylindrical hole communicating with the through portion TH0 of the under-electrode insulating material IM0 is formed in the resist FR0. Examples of the method of removing the resist FR0 include patterning.

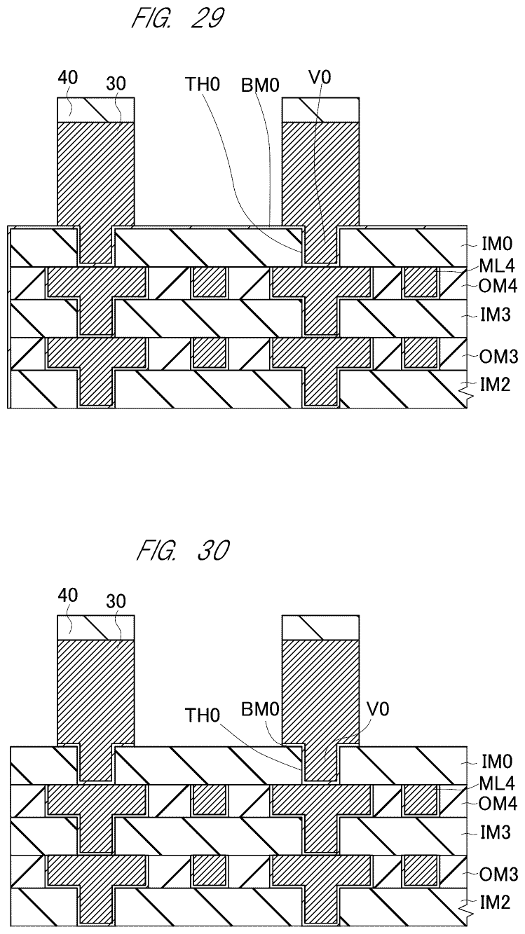

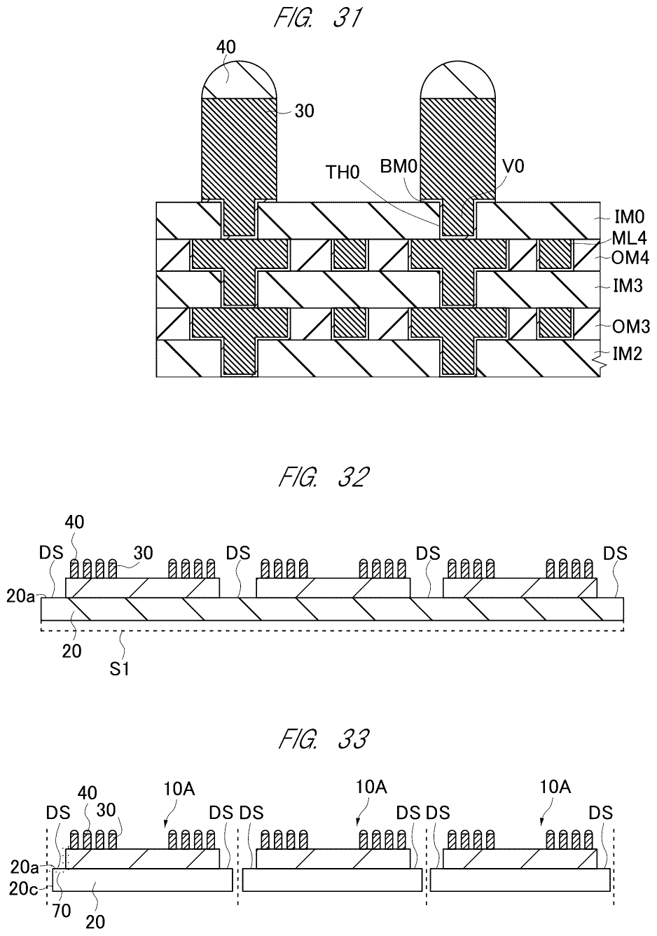

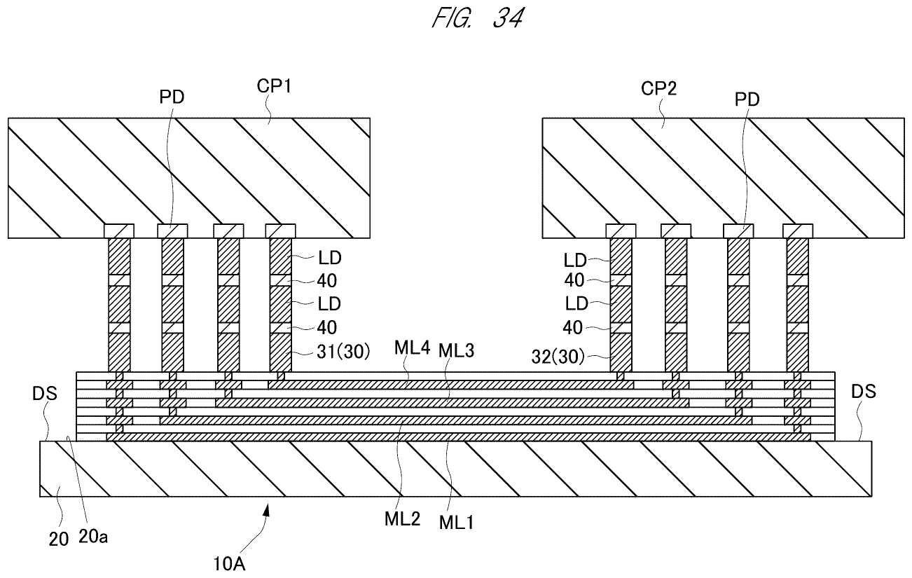

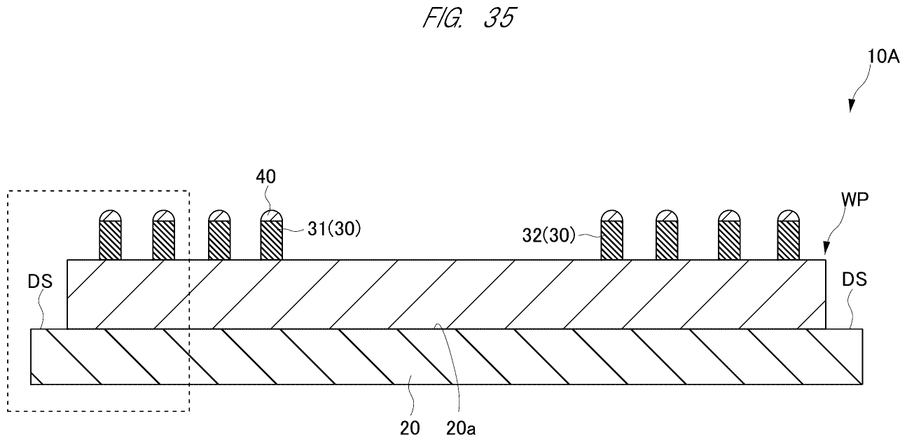

FIG. 28 is a cross-sectional view illustrating a step of the method of manufacturing the wiring device according to the other embodiment. As illustrated in FIG. 28, in the method of manufacturing the wiring device according to the other embodiment, an under-electrode via V0 is formed so as to fill the through portion TH0 of the under-electrode insulating material IM0. In addition, an electrode 30 is formed so as to fill the removed resist FR0. Furthermore, a conductive bonding material 40 is formed on the electrode 30 so as to fill the removed resist FR0. As illustrated in FIG. 28, the under-electrode via V0 and the electrode 30 are integrally formed. The under-electrode via V0 and the electrode 30 are, for example, Cu. The conductive bonding material 40 is, for example, solder. In the example illustrated in FIG. 28, the electrode 30 is in a cylindrical shape. The diameter of the electrode 30 is, for example, 10 μm or more and 25 μm or less. The height of the electrode 30 is, for example, 10 μm or more and 40 μm or less. The electrodes 30 are formed at pitches of 20 μm or more and 50 μm or less, for example.

FIG. 29 is a cross-sectional view illustrating a step of the method of manufacturing the wiring device according to the other embodiment. As illustrated in FIG. 29, the method of manufacturing the wiring device according to the other embodiment includes a step of removing the resist FR0. In addition, although not illustrated in FIG. 29, the resist FR0 covering the upper surface 20a of the substrate 20 serving as the dicing street DS is removed. As a result, the resist FR0 is entirely removed. The resist FR0 is removed using a peeling agent, for example.

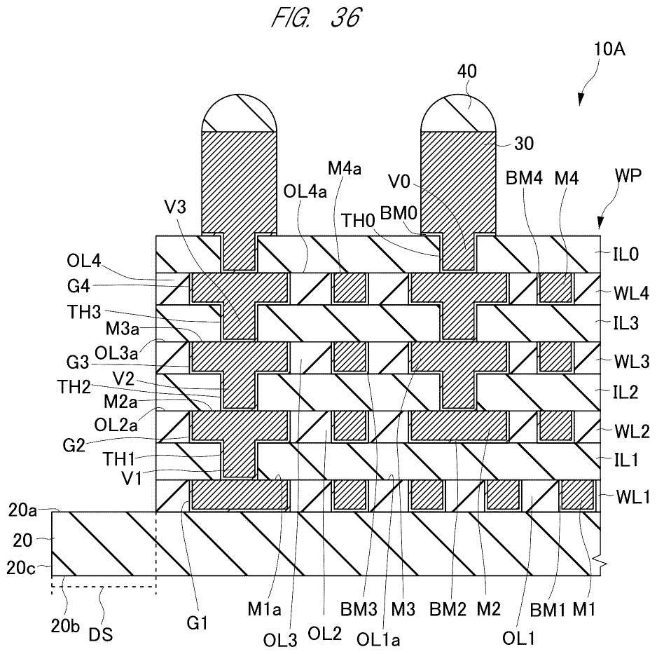

FIG. 30 is a cross-sectional view illustrating a step of the method of manufacturing the wiring device according to the other embodiment. As illustrated in FIG. 30, the method of manufacturing the wiring device according to the other embodiment includes a step of removing the seed layer BM0. Although not illustrated in FIG. 29, in the present embodiment, since the seed layer BM0 is formed, the upper surface 20a of the substrate 20 serving as the dicing street DS is covered with the seed layer BM0 even after the resist FR0 is removed. Therefore, after the resist FR0 is removed, the seed layer BM0 is removed such that the upper surface 20a of the substrate 20 serving as the dicing street DS is exposed. Examples of the method of removing the seed layer BM0 include etching.

FIG. 31 is a cross-sectional view illustrating a step of the method of manufacturing the wiring device according to the other embodiment. As illustrated in FIG. 31, the method of manufacturing the wiring device according to the other embodiment includes a step of reflowing a conductive bonding material 40.

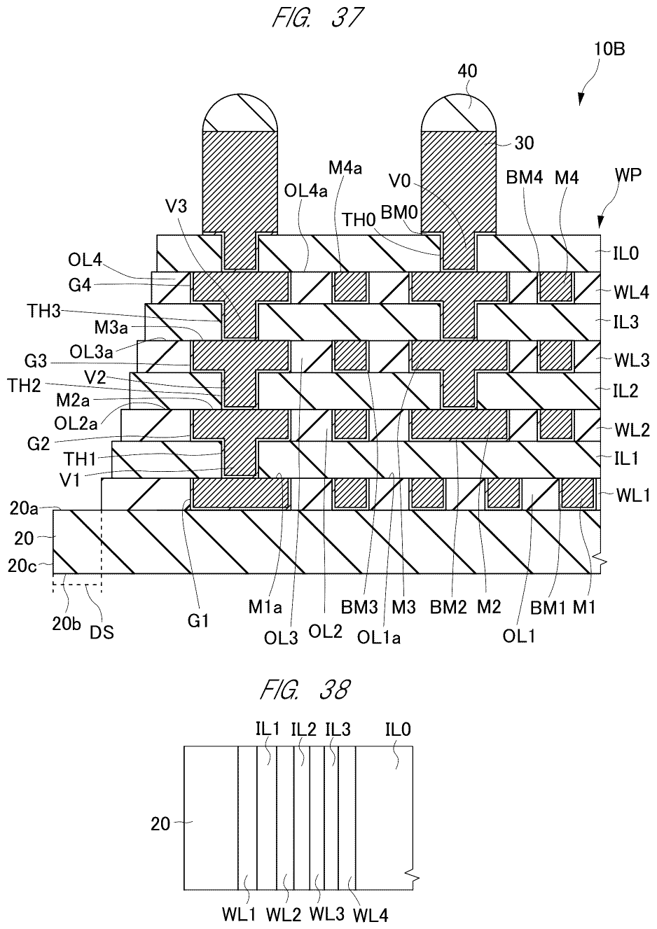

FIG. 32 is a cross-sectional view illustrating a step of the method of manufacturing the wiring device according to the other embodiment. The range of view of FIG. 32 is extended compared with the drawings up to FIG. 31. As illustrated in FIG. 32, the method of manufacturing the wiring device according to the other embodiment includes a step of removing a part of the substrate 20. As illustrated in FIG. 32, the thickness of the substrate 20 is reduced by backgrinding of a lower portion surface S1 of the substrate 20.

FIG. 33 is a cross-sectional view illustrating a step of the method of manufacturing the wiring device according to the other embodiment. As illustrated in FIG. 33, the method of manufacturing the wiring device according to the other embodiment includes a step of cutting a portion where the upper surface 20a of the substrate 20 is exposed. The portion where the upper surface 20a of the substrate 20 is exposed serves as the dicing street DS. By cutting the dicing street DS, the wiring device 10A can be singulated.

As illustrated in FIG. 33, a part of the dicing street DS remains after cutting. That is, the portion where the upper surface 20a of the substrate 20 is exposed remains. After cutting, the step portion 70 including the substrate 20 and the organic insulating material OM1 is formed.

As illustrated in FIG. 22, the method of manufacturing the wiring device according to the present embodiment can form the upper surface OM1a of the organic insulating material OM1 and the upper surface ML1a of the conductor layer ML1 on the same plane. In addition, the upper surface OM1a of the organic insulating material OM1 and the upper surface ML1a of the conductor layer ML1 are flat. Therefore, the lower portions of the wiring layers such as the interlayer organic insulating material IM1 and the organic insulating material OM2 formed on the organic insulating material OM1 can be flat. The wiring layers formed on the organic insulating material OM1 can be easily formed so as to have a uniform thickness. As a result, a broken wire can be prevented even in the case of thin wiring with a thickness of, for example, 2 μm or less.

Although the present embodiment uses the photosensitive resin for the interlayer organic insulating material IM1, the embodiment can be modified to a method that uses a non-photosensitive resin and opens the through portion TH1 by laser machining.

Although the present embodiment uses a photomask and a stepper exposure machine for patterning of the groove portion G1 of the organic insulating material OM1 and the through portion TH1 of the interlayer organic insulating material IM1, the embodiment can be modified to a method using a direct imaging exposure machine. In this case, the photomask can be omitted, and the time and cost for fabricating the mask can be reduced. In addition, the effect increases with an increase in the number of layers to be stacked and the number of masks that can be omitted.

### <Method of Manufacturing Semiconductor Device>

Next, a method of manufacturing a semiconductor device according to one embodiment will be described. The method of manufacturing the semiconductor device according to the present embodiment uses the wiring device manufactured by the above-described method of manufacturing the wiring device.

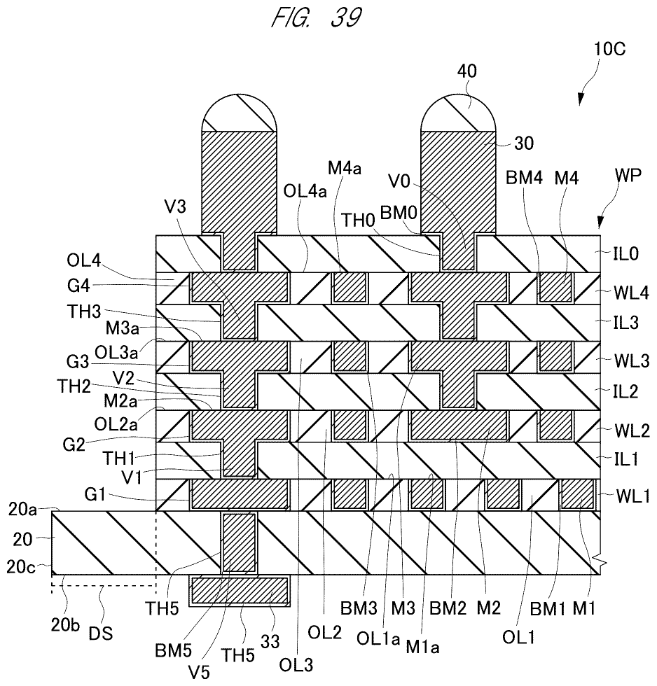

FIG. 34 is a cross-sectional view illustrating a step of the method of manufacturing the semiconductor device according to the one embodiment. As illustrated in FIG. 34, the method of manufacturing the semiconductor device according to the present embodiment includes a step of electrically connecting the wiring device 10A, a semiconductor chip CP1, and a semiconductor chip CP2. In the example illustrated in FIG. 34, the wiring device 10A is electrically connected to the semiconductor chip CP1 and the semiconductor chip CP2 by the conductive bonding material 40. The conductive bonding material 40 is, for example, solder. As illustrated in FIG. 34, the semiconductor chip CP1 is electrically connected to the semiconductor chip CP2 via the wiring device 10A. An electrode pad PD of the semiconductor chip CP1 is electrically connected to the conductor layer ML4 via a lead LD, the conductive bonding material 40, and an electrode 31 of the wiring device 10A. In addition, an electrode pad PD of the semiconductor chip CP2 is electrically connected to the conductor layer ML4 via the lead LD, the conductive bonding material 40, and an electrode 32 of the wiring device 10A.

### <Wiring Device>

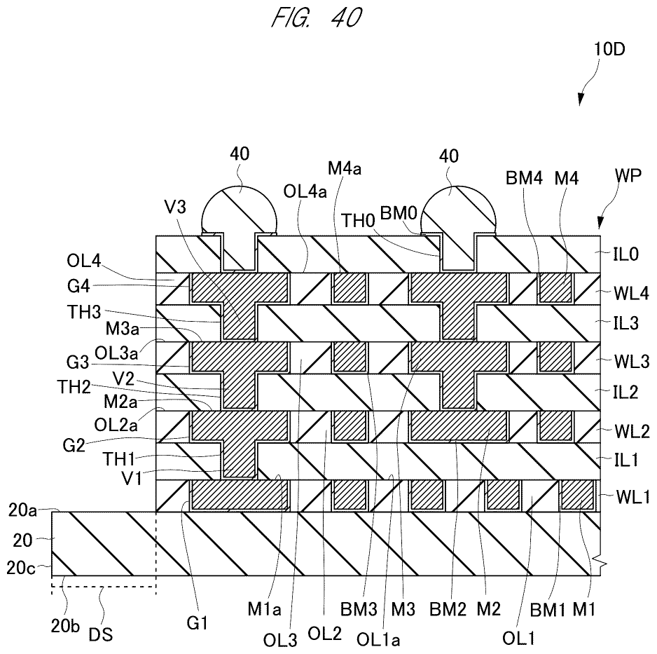

Next, a wiring device according to one embodiment will be described. FIG. 35 is a cross-sectional view illustrating the wiring device according to the one embodiment of the wiring device described with reference to FIGS. 1 to 33. FIG. 36 is an enlarged view of a portion surrounded by a dotted line of the wiring device illustrated in FIG. 35. As illustrated in FIG. 35, the wiring device 10A according to the present embodiment includes the substrate 20, a wiring portion WP, the electrode 30, and the conductive bonding material 40. In addition, as illustrated in FIG. 36, the wiring device 10A according to the present embodiment includes wiring layers WL0 to WL4, an under-electrode insulating layer IL0, interlayer organic insulating layers IL1 to IL3, the under-electrode via V0, vias V1 to V3, and the seed layers BM0 to BM4.

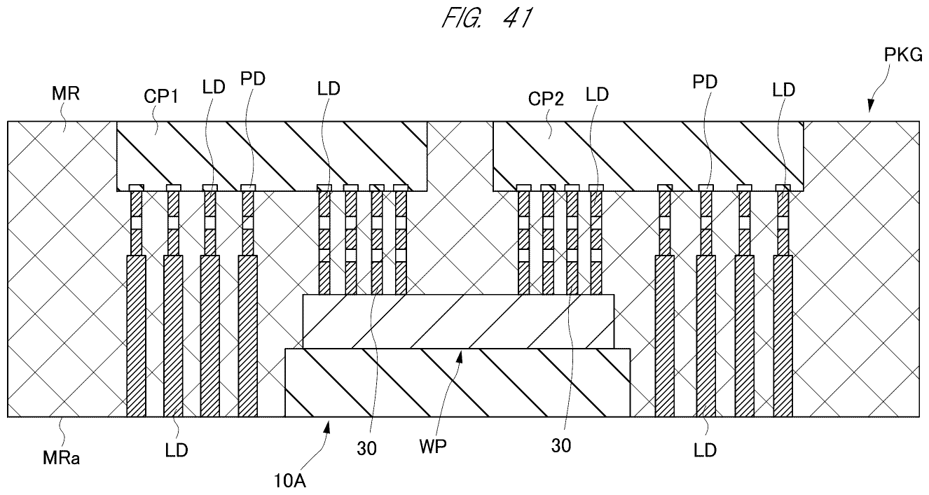

Next, a wiring device according to another embodiment will be described. FIG. 37 is a cross-sectional view illustrating the wiring device according to the other embodiment. FIG. 38 is a plan view of the wiring device illustrated in FIG. 37. As illustrated in FIG. 37, in the two upper and lower adjacent insulating layers, the outer peripheral side surface of the upper insulating layer is on the inner side from the outer peripheral side surface of the lower insulating layer in plan view. For example, a step portion is formed in the interlayer organic insulating layer IL1 and the organic insulating layer OL2 due to the positional relationship between the outer peripheral side surfaces of the interlayer organic insulating layer IL1 and the organic insulating layer OL2. That is, in a wiring device 10B, the step portion is formed like stairs by the plurality of insulating layers. This can further increase the surface area of the side surface portion of the wiring device 10B. As a result, when the wiring device 10B is sealed with a sealing body such as resin, the contact area between the sealing body and the wiring device can be further increased. Therefore, the mounting reliability of the wiring device 10B can be further improved. In addition, since the lower insulating layer protrudes from the upper insulating layer, the upper insulating layer can be prevented from protruding from the lower insulating layer during stacking of the insulating layers even if misalignment occurs in the range of processing accuracy. This can prevent the upper insulating layer from being misaligned and falling off. As a result, the lower insulating layer and the upper insulating layer are less likely to be separated from each other. In addition, as illustrated in FIG. 38, the outer edge of the wiring layer WL2 is on the inner side from the outer edge of the wiring layer WL1 in plan view. Although only a part of the step portion is illustrated in FIG. 38, the entire outer edge of the wiring layer WL2 may be formed on the inner side from the outer edge of the wiring layer WL1.

FIG. 39 is a cross-sectional view illustrating a wiring device 10C according to another embodiment. As illustrated in FIG. 39, a through portion TH5 is provided in the substrate 20. A through electrode V5 is embedded in the through portion TH5. The through electrode V5 is electrically connected to the wiring M1. An electrode 33 is provided on a lower surface 20b of the substrate 20. The through electrode V5 is electrically connected to the electrode 33. In the example illustrated in FIG. 39, a seed layer BM5 is provided between the through electrode V5 and the substrate 20. In addition, the seed layer BM5 is provided between the through electrode V5 and the wiring M1. That is, the through electrode V5 is electrically connected to the wiring M1 via the seed layer BM5. In addition, the seed layer BM5 is provided between the electrode 33 and the through electrode V5. That is, the through electrode V5 is electrically connected to the electrode 33 via the seed layer BM5. In the present embodiment, the substrate 20 is made of glass.

In the present embodiment, the electrode 33 provided on the lower surface 20b of the substrate 20 and the wiring M1 are electrically connected via the through electrode V5. As a result, the wiring M1 of the wiring portion WP can be electrically connected to wiring provided on the opposite side of the wiring portion WP across the substrate 20. Therefore, a semiconductor chip provided on the wiring portion WP side with respect to the substrate 20 can be electrically connected to a semiconductor chip provided on the opposite side of the wiring portion WP side across the substrate 20.

In addition, an electronic circuit such as a transistor circuit or an integrated circuit may be formed on the substrate of the wiring device 10C. This allows a wafer level chip size package (WLCSP) having fine wiring to be configured. Fine wiring enables rewiring from the electrode pad PD on the semiconductor chip CP1 by rearranging a terminal such as a columnar electrode and solder bump on the wiring device 10C. The wiring portion WP of the wiring device 10C is flatter than that of the conventional WLCSP. Therefore, the wiring can be finer with a high yield even when a plurality of wiring layers is stacked.

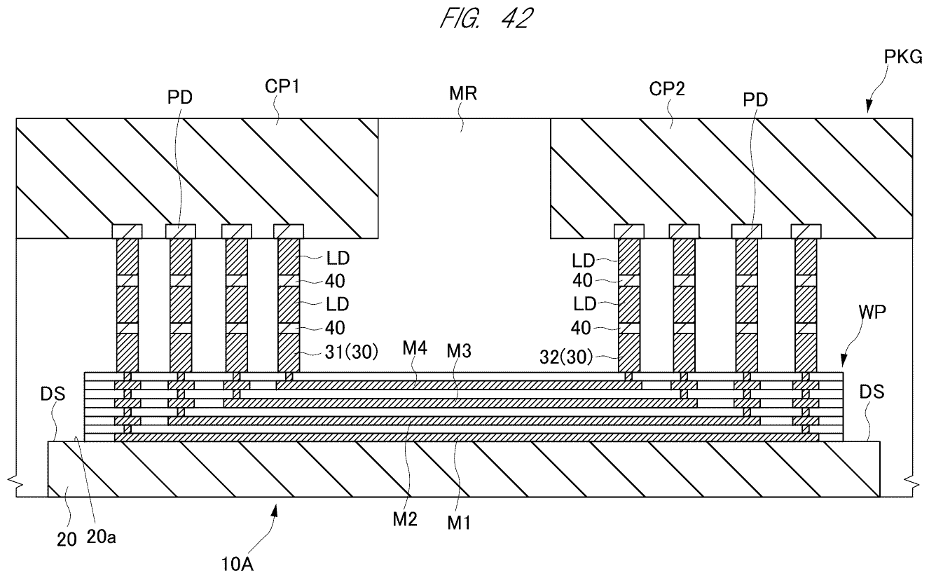

FIG. 40 is a cross-sectional view illustrating a wiring device 10D according to another embodiment. As illustrated in FIG. 40, the conductive bonding material 40 is embedded in the under-electrode insulating layer IL0. The electrode 30 illustrated in FIG. 36 is replaced with the conductive bonding material 40. In the present embodiment, the conductive bonding material 40 functions as the electrode 30. The conductive bonding material 40 is, for example, solder. Since the electrode 30 is replaced with the conductive bonding material 40, the step of forming the electrode 30 can be omitted.

Incidentally, in a case where silicon is used for the substrate, a through silicon via (TSV) formed so as to penetrate the silicon substrate may be provided, although not illustrated. A wiring device using a silicon substrate including the TSV is referred to as a silicon bridge. Manufacturing the silicon bridge having the TSV requires very expensive equipment and manufacturing process called a front-end process where the semiconductor integrated circuit is formed. Therefore, using glass for the substrate is preferable in that the manufacturing cost can be reduced as compared with the silicon bridge.

### <Semiconductor Device>

Next, a semiconductor device according to one embodiment will be described. FIG. 41 is a cross-sectional view illustrating the semiconductor device according to the one embodiment. FIG. 42 is an enlarged view of the semiconductor device illustrated in FIG. 41. As illustrated in FIG. 41, a semiconductor device PKG according to the present embodiment includes the wiring device 10A, the semiconductor chip CP1, the semiconductor chip CP2, a sealing body MR, and the plurality of leads LD.

In the present embodiment, the wiring device 10A is the wiring device 10A according to the above-described embodiment.

The semiconductor chip CP1 includes a plurality of electrode pads PD. Some of the electrode pads PD are electrically connected to the electrodes 30 of the wiring device 10A via the leads LD. In addition, the leads LD electrically connected to some of the electrode pads PD are exposed from a lower surface MRb of the sealing body MR.

The semiconductor chip CP2 includes a plurality of electrode pads PD. Some of the electrode pads PD are electrically connected to the electrodes 30 of the wiring device 10A via the leads LD. In addition, the leads LD electrically connected to some of the electrode pads PD are exposed from a lower surface MRb of the sealing body MR.

The sealing body MR seals the wiring device 10A, the semiconductor chip CP1, the semiconductor chip CP2, and the plurality of leads LD. The sealing body MR is made of, for example, a resin.

As illustrated in FIG. 42, the electrode pad PD of the semiconductor chip CP1 is electrically connected to the electrode pad PD of the semiconductor chip CP2 via the wiring portion WP of the wiring device 10A. For example, the electrode pad PD of the semiconductor chip CP1 is electrically connected to the electrode pad PD of the semiconductor chip CP2 via the electrode 31, wiring M4, and the electrode 32. Note that, in FIG. 42, hatching of the sealing body MR and the like is omitted for easy viewing.

Some representative embodiments have been described above with reference to the drawings, but the above-described embodiments and modifications further include various modifications. A part of the embodiment can be appropriately changed as long as there is no contradiction with the above description. In addition, for example, a part of the above-described embodiment or modification can be applied in combination with a part of another embodiment.

What is claimed is:

1. A method of manufacturing a wiring device comprising the steps of:
(a) preparing a substrate;
(b) forming a first insulating layer on an upper surface of the substrate;
(c) removing a part of the first insulating layer to form a groove portion;
(d) forming a first conductor layer so as to fill the groove portion of the first insulating layer; and
(e) machining a part of the first insulating layer and a part of the first conductor layer to form a first wiring layer.

2. The method of manufacturing a wiring device according to claim 1,
wherein machining in the step (e) is planer cutting.

3. The method of manufacturing a wiring device according to claim 2,
wherein the substrate is an inorganic substrate on which a circuit is not formed.

4. The method of manufacturing a wiring device according to claim 2, further comprising,
after the step (e), the step of (f) cutting a portion where the upper surface of the substrate is exposed to singulate the wiring device.

5. The method of manufacturing a wiring device according to claim 2,
wherein a surface roughness of an upper surface of the first wiring layer is Ra 0.01 μm or more and Ra 0.05 μm or less.

6. The method of manufacturing a wiring device according to claim 1, further comprising, after the step (e), the steps of:
(e1) forming a first interlayer insulating layer on the first wiring layer;
(e2) forming a through portion in the first interlayer insulating layer such that the first conductor layer is exposed;
(e3) forming a second insulating layer on the first interlayer insulating layer;
(e4) forming a groove portion by removing a part of the second insulating layer such that a through portion of the first interlayer insulating layer is exposed from the second insulating layer;
(e5) forming a second conductor layer so as to fill the through portion of the first interlayer insulating layer and the groove portion of the second insulating layer; and
(e6) machining a part of the second insulating layer and a part of the second conductor layer to form a second wiring layer,
wherein the first conductor layer is electrically connected to the second conductor layer.

7. The method of manufacturing a wiring device according to claim 6,
wherein machining in the step (e) and the step (e6) is planer cutting.

8. The method of manufacturing a wiring device according to claim 6,
wherein at least a part of an outer edge of the second wiring layer is on an inner side from an outer edge of the first wiring layer in plan view.
